(19) United States
(12) Patent Application Publication
(10) Pub. No.: US 2011/0147905 A1
(43) Pub. Date: Jun. 23, 2011

(54) SEMICONDUCTOR DEVICE AND METHOD OF MANUFACTURING THE SAME

(75) Inventors: Masaki Utsumi, Kyoto (JP); Hikari Sano, Hyogo (JP); Hiroaki Fujimoto, Osaka (JP); Yoshihiro Tomita, Osaka (JP)

(73) Assignee: PANASONIC CORPORATION, Osaka (JP)

(21) Appl. No.: 13/039,937

(22) Filed: Mar. 3, 2011

Related U.S. Application Data
(63) Continuation of application No. PCT/JP2009/004510, filed on Sep. 11, 2009.

(30) Foreign Application Priority Data
Nov. 21, 2008 (JP) 2008-297423

(51) Int. Cl. H01L 23/06; H01L 21/78

(52) U.S. Cl. 257/680; 438/113; 257/E23.191; 257/E21.599

(57) ABSTRACT

In a semiconductor element, upper through-hole conductor portions and lower through-hole conductor portions are formed such that pore size A of the joint surface of the upper through-hole conductor portion and the lower through-hole conductor portion is smaller than pore size B of the upper through-hole conductor portion on the major surface of the semiconductor element and pore size C of the lower through-hole conductor portion on the other surface of the semiconductor element. Further, electrode portions are formed respectively on the top surfaces of the upper through-hole conductor portions and protrusions 4 are formed respectively on the top surfaces of the electrode portions. Moreover, an optical member pressed in contact with the protrusions is fixed on the semiconductor element with an adhesive.

### FIELD OF THE INVENTION

The present invention relates to semiconductor devices used for digital cameras and cellular phones, for example, semiconductor devices including light receiving devices such as semiconductor image pickup devices and photo ICs, light emitting devices such as LEDs and lasers, and general semiconductor devices having various general purpose functions, and a method of manufacturing the same.

### BACKGROUND OF THE INVENTION

As electronic equipment has been recently reduced in size, thickness, and weight, high-density packaging for semiconductor devices has been increasingly demanded. Further, as semiconductor devices have been mounted with higher densities with advancements in micromachining technology, so-called chip packaging technology for directly mounting chip-size packages or bare chips has been proposed.

For example, as a semiconductor device according to the related art, U.S. Patent Application Publication 2008/0042227 proposes a device structure and a method of manufacturing the same in which the thickness of a semiconductor image pickup device is reduced at lower cost by bonding a transparent plate on the image pickup region of a semiconductor element with an adhesive in the semiconductor image pickup device. In this manufacturing method, as shown in FIG. 6, a protective member 24 made of, e.g., glass is fixed with an adhesive 23 on a semiconductor element 22 having an image pickup region 21 thereon, through holes 26 are formed directly under electrodes 25 of the semiconductor element 22, and an insulating layer 27 is formed on the inner walls of the through holes 26 and the underside of the semiconductor element 22. After that, the electrodes 25 and external electrodes 30 formed on the underside of the semiconductor element 22 are electrically connected to each other via conductor layers 28, so that the semiconductor image pickup device is obtained. In this manufacturing method, the external size of the semiconductor image pickup device is a so-called chip size as small as the semiconductor element 22, achieving a size reduction.

### DISCLOSURE OF THE INVENTION

In the semiconductor device of the related art, however, the through holes 26 of the semiconductor element 22 are configured so as to extend near the external electrodes 30. Therefore, the conductor layers 28 in the through holes 26 may fall off the semiconductor device due to, e.g., a stress generated when the semiconductor device is mounted on an electronic device substrate (in the configuration of FIG. 6, a stress applied downward in FIG. 6), causing an electrical short circuit between the semiconductor device and the electronic device substrate. Further, since the through holes 26 of the semiconductor element 22 are extended near the external electrodes 30, small cracks are likely to occur in the through holes 26, deteriorating the electrical characteristics of the semiconductor device.

Therefore, a disadvantage of the semiconductor device of the related art is a reduction in product yield (the yield of the semiconductor device). A reduction in yield increases the cost of the product. Another disadvantage is a reduction in reliability and mass productivity.

The present invention has been devised to solve the problem of the related art. Specifically, an object of the present invention is to provide a semiconductor device and a method of manufacturing the same which can suppress a reduction in product yield and obtain a device structure with high reliability and mass productivity while suppressing an increase in product cost.

In order to attain the object, a first semiconductor device of the present invention includes: a semiconductor element including a major surface, the other surface opposite to the major surface, first electrode portions formed on the major surface, protrusions connected on the respective first electrode portions, through-hole conductor portions that are located directly under the respective first electrode portions and penetrate the semiconductor element between the major surface and the other surface, and external electrodes formed on the other surface; and a retaining member that covers the protrusions and the first electrode portions and is joined to the semiconductor element while being held by the semiconductor element via the protrusions, wherein the through-hole conductor portions are increased in pore size from the inside of the semiconductor element to the major surface and the other surface, and the first electrode portions are electrically connected to the respective external electrodes via the respective through-hole conductor portions.

With this configuration, it is possible to reduce the possibility that the through-hole conductor portions would fall off the semiconductor device due to a stress generated when the semiconductor device is mounted on an electronic device substrate. This configuration can eliminate electrical short circuits between the semiconductor device and the electronic device substrate, so that a reliable semiconductor device can be provided. Moreover, it is possible to reduce the possibility of small cracks on the through-hole conductor portions, so that the electrical characteristics of the semiconductor device are not degraded. Hence, a reliable semiconductor device can be provided.

Further, a second semiconductor device of the present invention includes: a semiconductor element including a major surface, the other surface opposite to the major surface, first electrode portions formed on the major surface, protrusions connected on the respective first electrode portions, through-hole conductor portions that are located directly under the respective first electrode portions and penetrate the semiconductor element between the major surface and the other surface, and external electrodes formed on the other surface; and a retaining member that covers the protrusions and the first electrode portions and is joined to the semiconductor element while being held by the semiconductor element via the protrusions, wherein the through-hole conductor portions are increased in pore size from the inside of the semiconductor element to the major surface and substantially have a constant pore size from the inside of the semiconductor element to the other surface, and the first electrode portions are electrically connected to the respective external electrodes via the respective through-hole conductor portions.

With this configuration, a reliable semiconductor device can be provided. When the through-hole conductor portions are formed by etching or the like, only one surface of the semiconductor element requires etching, thereby suppressing an increase in manufacturing cost.

In the first and second semiconductor devices of the present invention, the retaining member may be an optical member bonded to the semiconductor element while being in contact with the protrusions. Alternatively, the retaining member may be another semiconductor element that has second electrode portions and is electrically connected to the semiconductor element with the second electrode portions joined to the respective protrusions.

Moreover, a third semiconductor device of the present invention includes: a semiconductor element including a major surface, the other surface opposite to the major surface, first electrode portions formed on the major surface, through-hole conductor portions that are located directly under the respective first electrode portions and penetrate the semiconductor element between the major surface and the other surface, and external electrodes formed on the other surface; and an optical member bonded to the semiconductor element so as to cover the first electrode portions, wherein the through-hole conductor portions are increased in pore size from the inside of the semiconductor element to the major surface, and the first electrode portions are electrically connected to the respective external electrodes via the respective through-hole conductor portions.

With this configuration, it is possible to reduce the possibility that the through-hole conductor portions would fall off the semiconductor device due to a stress generated when the semiconductor device is mounted on an electronic device substrate. This configuration can eliminate electrical short circuits between the semiconductor device and the electronic device substrate, so that a reliable semiconductor device can be provided. Moreover, it is possible to reduce the possibility of small cracks on the through-hole conductor portions, so that the electrical characteristics of the semiconductor device are not degraded. Hence, a reliable semiconductor device can be provided.

In the third semiconductor device of the present invention, the through-hole conductor portions may be increased in pore size from the inside of the semiconductor element to the major surface and the other surface. Alternatively, the through-hole conductor portions may be increased in pore size from the inside of the semiconductor element to the major surface and substantially have a constant pore size from the inside of the semiconductor element to the other surface.

A first method of manufacturing a semiconductor device according to the present invention includes the steps of: forming multiple semiconductor elements in a semiconductor wafer; forming upper through-hole conductor portions on the major surface of the semiconductor wafer for the semiconductor element such that the upper through-hole conductor portions are increased in pore size from the inside of the semiconductor wafer to the major surface; forming first electrode portions respectively on the top surfaces of the upper through-hole conductor portions; connecting protrusions respectively to the top surfaces of the first electrode portions; joining a retaining member to the semiconductor wafer such that the retaining member covers the protrusions and the first electrode portions and is held by the semiconductor wafer via the protrusions; forming holes serving as lower through-hole conductor portions nearly under the respective first electrode portions, by polishing the other surface opposite to the major surface of the semiconductor wafer, the holes reaching the upper through-hole conductor portions and being increased in pore size from the inside of the semiconductor wafer to the other surface; forming an insulating film on the inner walls of the holes serving as the lower through-hole conductor portions and the other surface of the semiconductor wafer; forming the lower through-hole conductor portions and external electrodes by forming a conductor layer on the insulating film on the inner walls of the holes serving as the lower through-hole conductor portions and on the other surface of the semiconductor wafer, the lower through-hole conductor portion being electrically connected to the first electrode portion via the upper through-hole conductor portion, the external electrode being electrically connected to the lower through-hole conductor portion; and cutting the semiconductor wafer for each of the semiconductor elements to obtain individual semiconductor devices.

A second method of manufacturing a semiconductor device according to the present invention includes the steps of: forming multiple semiconductor elements in a semiconductor wafer; forming upper through-hole conductor portions on the major surface of the semiconductor wafer for the semiconductor element such that the upper through-hole conductor portions are increased in pore size from the inside of the semiconductor wafer to the major surface; forming first electrode portions respectively on the top surfaces of the upper through-hole conductor portions; connecting protrusions respectively to the top surfaces of the first electrode portions; joining a retaining member to the semiconductor wafer such that the retaining member covers the protrusions and the first electrode portions and is held by the semiconductor wafer via the protrusions; polishing the other surface opposite to the major surface of the semiconductor wafer; forming holes serving as lower through-hole conductor portions nearly under the respective first electrode portions on the other surface of the semiconductor wafer, the holes reaching the upper through-hole conductor portions and being increased in pore size from the inside of the semiconductor wafer to the other surface or substantially having a constant pore size from the inside of the semiconductor wafer to the other surface; forming an insulating film on the inner walls of the holes serving as the lower through-hole conductor portions and the other surface of the semiconductor wafer; forming the lower through-hole conductor portions and external electrodes by forming a conductor layer on the insulating film on the inner walls of the holes serving as the lower through-hole conductor portions and on the other surface of the semiconductor wafer, the lower through-hole conductor portion being electrically connected to the first electrode portion via the upper through-hole conductor portion, the external electrode being electrically connected to the lower through-hole conductor portion; and cutting the semiconductor wafer for each of the semiconductor elements to obtain individual semiconductor devices.

In the first and second methods of manufacturing the semiconductor device according to the present invention, the retaining member may be an optical member. The optical member is bonded to the semiconductor wafer while being in contact with the protrusions. Alternatively, the retaining member may be another semiconductor element that has second electrode portions formed thereon. The other semiconductor element is electrically connected to the semiconductor wafer with the second electrode portions joined to the respective protrusions.

A third method of manufacturing a semiconductor device according to the present invention includes the steps of: forming multiple semiconductor elements in a semiconductor wafer; forming upper through-hole conductor portions on the major surface of the semiconductor wafer for the semiconductor element such that the upper through-hole conductor portions are increased in pore size from the inside of the semiconductor wafer to the major surface; forming first electrode portions respectively on the top surfaces of the upper through-hole conductor portions; bonding an optical member to the semiconductor wafer such that the optical member covers the first electrode portions; polishing the other surface opposite to the major surface of the semiconductor wafer; forming holes serving as lower through-hole conductor portions nearly under the respective first electrode portions on the other surface of the semiconductor wafer, the holes reaching the upper through-hole conductor portions and being increased in pore size from the inside of the semiconductor wafer to the other surface or substantially having a constant pore size from the inside of the semiconductor wafer to the other surface; forming an insulating film on the inner walls of the holes serving as the lower through-hole conductor portions and the other surface of the semiconductor wafer; forming the lower through-hole conductor portions and external electrodes by forming a conductor layer on the insulating film on the inner walls of the holes serving as the lower through-hole conductor portions and on the other surface of the semiconductor wafer, the lower through-hole conductor portion being electrically connected to the first electrode portion via the upper through-hole conductor portion, the external electrode being electrically connected to the lower through-hole conductor portion; and cutting the semiconductor wafer for each of the semiconductor elements to obtain individual semiconductor devices.

These methods can provide a reliable semiconductor device.

According to a preferred embodiment of the present invention, it is possible to reduce the possibility that the through-hole conductor portions would fall off the semiconductor device due to a stress generated when the semiconductor device is mounted on an electronic device substrate. Thus electrical short circuits between the semiconductor device and the electronic device substrate can be eliminated, so that a reliable semiconductor device can be provided.

According to the preferred embodiment of the present invention, it is possible to reduce the possibility of small cracks on the through-hole conductor portions, so that the electrical characteristics of the semiconductor device are not degraded. Hence, a reliable semiconductor device can be provided.

The preferred embodiment of the present invention can provide a method of manufacturing the reliable semiconductor device.

Consequently, it is possible to shorten the time for the manufacturing process, suppress a reduction in the yield of the semiconductor device, obtain a device structure that has high reliability and mass productivity and is suitable for the size reduction of a product in which the semiconductor device is mounted, and reduce the thickness and size of the product while suppressing an increase in the cost of the semiconductor device. Therefore, the present invention is useful in the field of, e.g., digital cameras and cellular phones which will increasingly require higher performance, a smaller thickness, and a smaller size in the future.

### BRIEF DESCRIPTION OF THE DRAWINGS

FIGS. 1A to 1F are schematic process sectional views showing a method of manufacturing a semiconductor device according to an embodiment of the present invention;

FIG. 2 is a detailed sectional view showing a basic structural example of a through-hole conductor portion in the semiconductor device according to the embodiment of the present invention;

FIG. 3 is a detailed sectional view showing another structural example 1 of the through-hole conductor portion in the semiconductor device according to the embodiment of the present invention;

FIG. 4 is a detailed sectional view showing another structural example 2 of the through-hole conductor portion in the semiconductor device according to the embodiment of the present invention;

FIGS. 5A to 5E are schematic process sectional views showing another method of manufacturing the semiconductor device according to the embodiment of the present invention;

FIG. 6 is a sectional view showing the structure of a semiconductor device according to the related art;

FIG. 7A is a plan view showing a structural example of an LED according to the embodiment of the present invention;

FIG. 7B is a sectional view showing a structural example of the LED according to the embodiment of the present invention; and

FIG. 8 is a sectional view showing a structural example of a general semiconductor device according to the embodiment of the present invention.

### DESCRIPTION OF THE EMBODIMENTS

A semiconductor device and a method of manufacturing the same according to an embodiment of the present invention will be specifically described below in accordance with the accompanying drawings.

In the drawings, the main constituent elements are schematically illustrated and the shapes of the constituent elements are not precisely shown for the sake of simplicity.

First, as an example of the semiconductor device of the present embodiment, a semiconductor image pickup device will be described that is a kind of light receiving device.

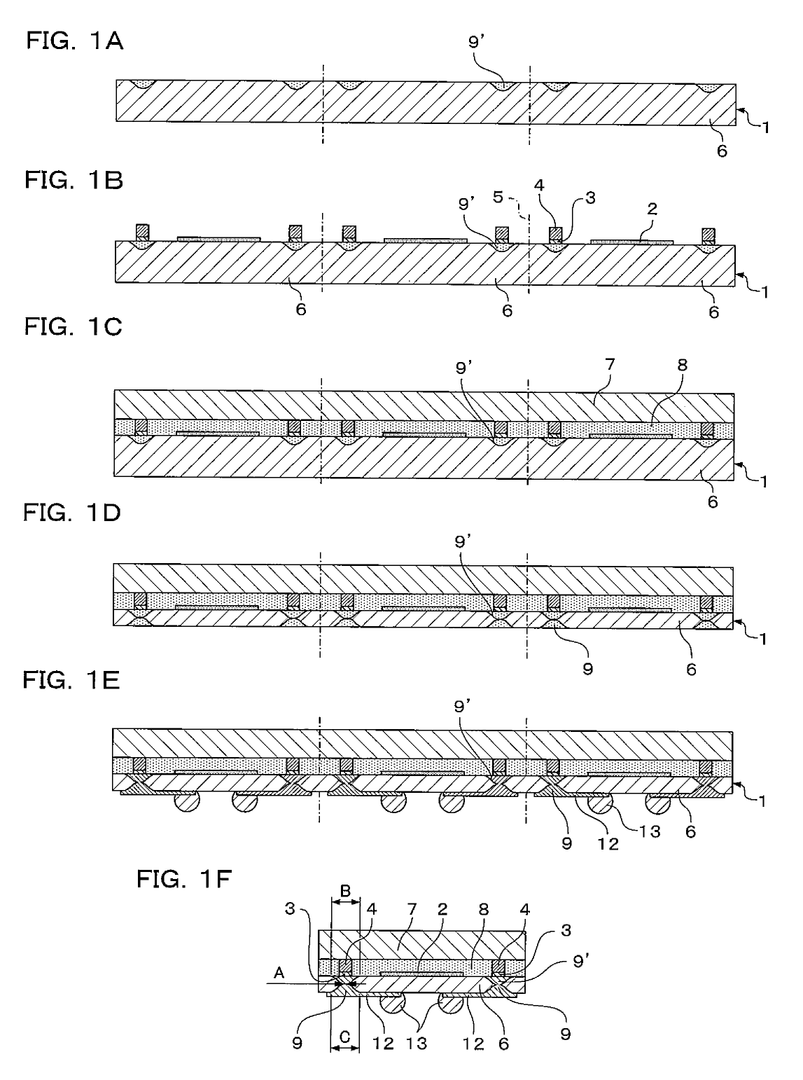

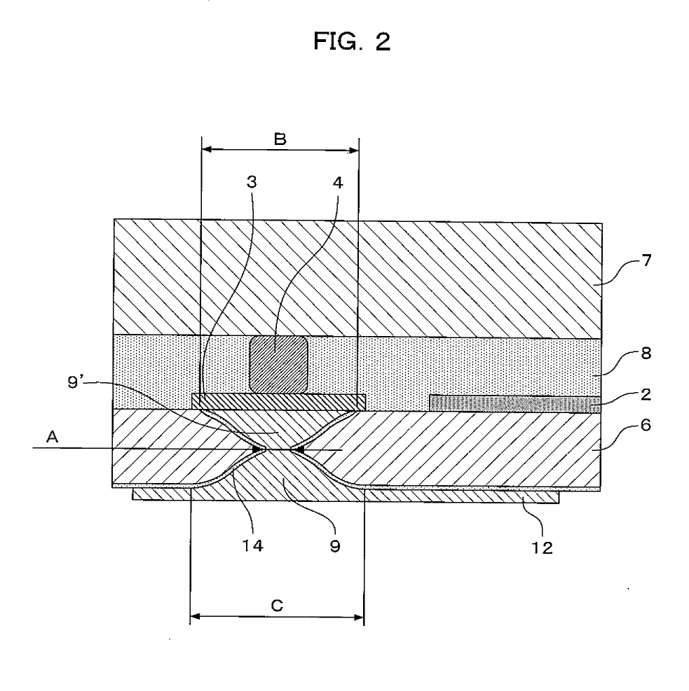

FIGS. 1A to 1F are schematic process sectional views showing the method of manufacturing the semiconductor image pickup device serving as the semiconductor device of the present embodiment. FIG. 2 is a detailed sectional view showing a through-hole conductor portion in the semiconductor image pickup device serving as the semiconductor device of the present embodiment.

In FIGS. 1A to 1F and 2, reference numeral 1 denotes a semiconductor wafer, reference numeral 2 denote an image pickup region, reference numeral 3 denotes electrode portions (first electrode portions), reference numeral 4 denotes protrusions, reference numeral 5 denotes cutting-plane lines, reference numeral 6 denotes semiconductor elements, reference numeral 7 denotes an optical member serving as a retaining member on the semiconductor element 6, reference numeral 8 denotes an adhesive (transparent adhesive member), reference numeral 9 denotes lower through-hole conductor portions, reference numeral 9′ denotes upper through-hole conductor portions, reference numeral 12 denotes external electrodes (conductor layers), reference numeral 13 denotes solder balls, and reference numeral 14 denotes insulating films.

First, as shown in FIG. 1A, the semiconductor wafer 1 is divided along virtual lines at equal intervals to form the semiconductor elements 6 in the semiconductor wafer 1. Further, the upper through-hole conductor portions 9′ are formed at points directly under the electrode portions 3 of the semiconductor element 6. The upper through-hole conductor portions 9′ are formed as follows: a resist or the like is selectively formed on the surface of the semiconductor wafer 1 and the exposed portions of the surface of the semiconductor wafer 1 are etched by plasma etching or wet etching, thereby forming holes serving as the upper through-hole conductor portions 9′. The holes are filled with a conductive material after the insulating films 14 are formed on the inner walls of the holes.

Next, as shown in FIG. 1B, the image pickup region 2 and the electrode portions 3 are formed at predetermined positions on each of the semiconductor elements 6 having been cut along the virtual lines at equal intervals in the semiconductor wafer 1, and then the protrusions 4 are respectively formed on the electrode portions 3 of the semiconductor elements 6.

In this configuration, the semiconductor wafer 1 is a disc-like semiconductor substrate that is made of, e.g., silicon, germanium, or compound semiconductor materials (including GaAs, InP, GaN, and SiC), has a thickness of about 100 μm to 800 μm, and has a diameter of about 2 inches to 15 inches.

The protrusions 4 are formed on the electrode portions 3 by so-called ball bumping. Specifically, spherical protrusions formed on the ends of thin gold wires (Au wires) are bonded onto the electrode portions 3 of the semiconductor element 6 by methods such as ultrasonic thermocompression bonding using a wire bonder. The used Au wires are about 15 μm to 30 μm in diameter and the spherical protrusions formed on the ends of the Au wires are about 30 μm to 90 μm in diameter. The spherical Au protrusions are subjected to ultrasonic thermocompression bonding under a load of about 10 g to 100 g at a heating temperature of about 80° C. to 150° C. The protrusions 4 formed thus are about 40 μm to 150 μm in diameter and are about 10 μm to 80 μm in thickness.

According to this method, the dimensions of the protrusions 4 can be set with extremely high precision. Thus a constant distance can be kept between the optical member 7, which serves as a retaining member to be bonded on the semiconductor element 6 later, and the surfaces of the image pickup regions 2 on the semiconductor elements 6. It is therefore possible to obtain a semiconductor image pickup device having a high-quality structure with suppressed variations.

Alternatively, the protrusions 4 may be formed by plating the electrode portions 3 with, e.g., Ni, Au, and Cu, or selectively forming a photosensitive resin on the electrode portions 3 by photolithography.

In any forming method, the protrusions 4 have higher stiffness than the adhesive 8 that bonds the optical member 7 later. In other words, the adhesive 8 is deformed larger than the protrusions 4 relative to a stress. The protrusions 4 made of metals such as Au in the present embodiment have a modulus of elasticity of about 10 GPa to 300 GPa, whereas the adhesive 8 is typically made of resins such as epoxy, silicone, and acrylic resins which are not contained in fillers, and the adhesive 8 typically has a modulus of elasticity of about 0.01 GPa to 10 GPa. Thus a deformation of the adhesive 8 can be easily made larger than that of the protrusions 4 relative to a stress.

Next, as shown in FIG. 1C, the optical member 7 made of, e.g., glass is fixed on the semiconductor wafer 1 with the adhesive 8 so as to cover the surfaces of the image pickup regions 2 on the semiconductor elements 6 formed in the semiconductor wafer 1.

The optical member 7 is made of materials such as glass and resin and has a thickness of about 0.05 mm to 1.0 mm. The optical member 7 has the same size as the semiconductor wafer 1 and is about 2 inches to 15 inches in diameter. The adhesive S is made of resins such as epoxy, silicone, and acrylic resins.

The optical member 7 is fixed as follows: the adhesive 8 is first applied over the semiconductor wafer 1 by a dispenser, a printing method, or spin coating using a spinner, and then the optical member 7 is placed on the semiconductor wafer 1. At this point, the optical member 7 is pressed in contact with the protrusions 4.

In the forming method of the protrusions 4, the protrusions 4 are formed on the electrode portions 3 before the optical member 7 is placed. Instead of this forming method, the protrusions 4 may be formed beforehand on the optical member 7 so as to be aligned with the electrode portions 3, and then the protrusions 4 may be placed on the semiconductor wafer 1 upon the placement of the optical member 7.

In this method, the adhesive 8 is first applied over the semiconductor wafer 1 and then the optical member 7 is placed thereon. Instead of the order of application, the adhesive 8 may be applied as follows: the optical member 7 is first placed on the semiconductor wafer 1 and temporarily fixed thereon before the application of the adhesive 8, and then the adhesive 8 is injected into a gap formed between the semiconductor wafer 1 and the optical member 7 by the protrusions 4. At this point, the adhesive 8 is injected in a vacuum and thus can be formed on the semiconductor wafer 1 in a short time without forming air bubbles.

Next, the adhesive 8 is cured to complete the fixation of the optical member 7. When the adhesive 8 is an ultraviolet curing adhesive, the adhesive 8 is cured by ultraviolet radiation through the optical member 7. When the adhesive 8 is a thermosetting adhesive, the adhesive 8 is cured by heat at 50° C. to 200° C. from a curing oven, a hot plate, an infrared lamp, and so on.

Subsequently, as shown in FIG. 1D, the underside of the semiconductor wafer 1 is polished to reduce the thickness of the semiconductor wafer 1. The polished semiconductor wafer 1 has a thickness of about 10 μm to 500 μm. The semiconductor wafer 1 is polished by mechanical polishing in which the pressed semiconductor wafer 1 is polished by a rotating grindstone, or the semiconductor wafer 1 is polished by dry etching.

In the case of mechanical polishing, since the protrusions 4 have higher stiffness than the adhesive 8, a pressure applied to the semiconductor wafer 1 concentrates on areas of the semiconductor wafer 1, directly under the protrusions 4. The areas directly under the protrusions 4 are polished more than the other areas of the semiconductor wafer 1, so that recessed holes for the respective lower through-hole conductor portions 9 are formed directly under the protrusions 4 in the semiconductor wafer 1. The recessed holes for the respective lower through-hole conductor portions 9 are about 10 μm to 200 μm in diameter and are about 3 μm to 100 μm in depth.

The recessed holes for the respective lower through-hole conductor portions 9 may be formed by the etching method of FIG. 1A.

Next, on the inner walls of the recessed holes for the respective lower through-hole conductor portions 9 and over the underside of the semiconductor wafer 1, an insulating film such as a silicon oxide film is formed (not shown). After that, the insulating films 14 at the bottoms of the upper through-hole conductor portions 9′ are removed by, e.g., photoetching. Subsequently, as shown in FIG. 1E, the conductor layers (lower through-hole conductor portions) 9 are formed in the recessed holes for the respective lower through-hole conductor portions 9, and the conductor layer 12 is selectively formed on the underside of the semiconductor wafer 1. The conductor layer 12 acts as the external electrodes 12 and the solder balls 13 are formed in the areas of the external electrodes 12. The upper through-hole conductor portions 9′ and the lower through-hole conductor portions 9 are electrically connected to each other, so that the semiconductor element 6 having the electrode portions 3 is electrically connected to the external electrodes 12.

When the conductor layers are formed in the recessed holes for the respective lower through-hole conductor portions 9 and the upper through-hole conductor portions 9′ of FIGS. 1A and 1E, the volume of the conductor layer and the amount of processing of the conductor layer may be reduced by applying, e.g., a resin into the recessed holes such that the surfaces of the conductor layers are in contact with the electrode portions 3 and the external electrodes (conductor layers) 12 with areas suitable for a required electric quantity of the semiconductor device.

Further, by forming asperities on the inner surfaces of the recessed holes for the lower through-hole conductor portions 9 and the upper through-hole conductor portions 9′, a contact area between the through-hole conductor portion (conductor layer) and the semiconductor element 6 is increased, so that the through-hole conductor portion including the lower through-hole conductor portion 9 and the upper through-hole conductor portion 9′ becomes less likely to drop off the semiconductor device.

In this configuration, the upper through-hole conductor portions 9′ are located directly under the electrode portions 3. The joint surface of the upper through-hole conductor portion 9′ and the lower through-hole conductor portion 9 has pore size A that is smaller than pore size B of the upper through-hole conductor portion 9′ on the major surface of the semiconductor element 6 and pore size C of the lower through-hole conductor portion 9 on the other surface of the semiconductor element 6, reducing the possibility that the through-hole conductor portion would fall off the semiconductor image pickup device due to a stress generated when the semiconductor device (semiconductor image pickup device) is mounted on an electronic device substrate. Thus it is possible to eliminate electrical short circuits between the semiconductor image pickup device and the electronic device substrate and provide a reliable semiconductor device. Moreover, it is possible to reduce the possibility of small cracks on the through-hole conductor portions 9 and 9′, so that the electrical characteristics of the semiconductor image pickup device are not degraded and a reliable semiconductor image pickup device (semiconductor device) can be provided.

FIG. 2 is a detailed sectional view showing the upper through-hole conductor portion 9′ and the lower through-hole conductor portion 9. The insulating films 14 illustrated in FIG. 1E can be easily formed by a silicon oxide film forming method using plasma CVD or a forming method of resins such as polyimide by spin coating.

The insulating films 14 are temporarily formed at the bottoms of the upper through-hole conductor portions 9′. After photoresist is selectively formed by photolithography, the insulating films 14 at the bottoms of the upper through-hole conductor portions 9′ are removed by, e.g., plasma etching or wet etching.

The upper through-hole conductor portions 9′ and the lower through-hole conductor portions 9 are formed by depositing, e.g., a Ti/Cu film by sputtering or the like and then forming a film made of metals such as Ni, Cu, and Au by electrolytic plating. The metal film has a thickness of about 0.1 μm to 2 μm. Before the metal film of the lower through-hole conductor portion 9 is deposited by sputtering, a surface at the pore size A of the upper through-hole conductor portion 9′ is slightly etched by dry etching or wet etching such that the contact surface of the lower through-hole conductor portion 9 (the metal film: a portion at the pore size A) with the upper through-hole conductor portion 9′ can be connected to the bottom of the-upper through-hole conductor portion 9′ (the metal film: a portion at the pore size A) at low resistance. At this point of time, the pore size B of the contact surface of the upper through-hole conductor portion 9′ with the electrode portion 3 is larger than the pore size A of the contact surface of the upper through-hole conductor portion 9′ and the lower through-hole conductor portion 9, so that the upper through-hole conductor portion 9′ is not lost by overetching and the yield does not decrease.

The through-hole conductor portions are formed by plating methods such as electrolytic plating and electroless plating. When the upper through-hole conductor portions 9′ are formed by plating, a plating solution easily comes into the recessed holes for the upper through-hole conductor portions 9′ because the pore size B is larger than the pore size A in the upper through-hole conductor portions 9′. Similarly, when the lower through-hole conductor portions 9 are formed by plating, a plating solution easily comes into the recessed holes for the lower through-hole conductor portions 9 because the pore size C is larger than the pore size A in the lower through-hole conductor portions 9. The upper through-hole conductor portions 9′ and the lower through-hole conductor portions 9 can be easily formed thus. FIG. 1E shows a structure in which the upper through-hole conductor portions 9′ and the lower through-hole conductor portions 9 are filled with the conductor layers. The volume of the conductor layer or the amount of processing of the conductor layer may be reduced by applying, e.g., a resin into the recessed holes such that the surfaces of the conductor layers are in contact with the electrode portions 3 and the external electrodes (conductor layers) 12 with areas suitable for a required electric quantity of the semiconductor device.

Next, as shown in FIG. 1F, the semiconductor wafer 1 is divided into individual semiconductor devices along the cutting-plane lines 5, so that the individual semiconductor image pickup devices are obtained. When the semiconductor wafer 1 is divided into the semiconductor image pickup devices, the optical member 7 and the semiconductor wafer 1 are simultaneously cut by methods such as dicing.

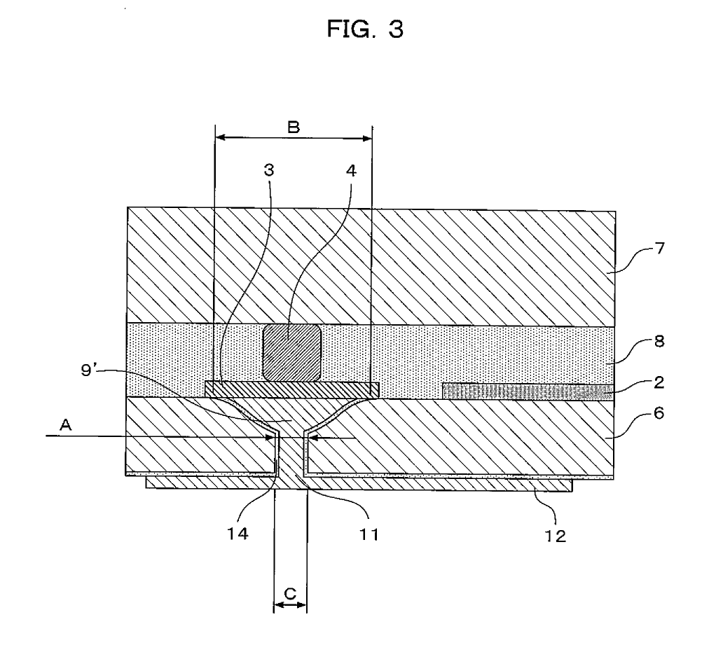

Referring to FIG. 3, a semiconductor image pickup device will be described below as a semiconductor device.

FIG. 3 is a detailed sectional view of an upper through-hole conductor portion 9′ and a through hole (conductor layer) 11. In FIG. 3, the upper through-hole conductor portion 9′ has pore size B that is larger than pore size A and the through hole (conductor layer) 11 has pore size C that is equal to the pore size A. Also in this case, it is possible to reduce the possibility that the upper through-hole conductor portion 9′ would fall off the semiconductor image pickup device due to a stress generated when the semiconductor image pickup device is mounted on an electronic device substrate. This configuration can eliminate electrical short circuits between the semiconductor image pickup device and the electronic device substrate, thereby providing a reliable semiconductor image pickup device. The through hole (conductor layer) 11 can be formed by boring with a drill or the like. Further, only one surface of the semiconductor wafer requires etching in the formation of the upper through-hole conductor portions 9′, thereby providing a reliable semiconductor image pickup device while suppressing an increase in manufacturing cost.

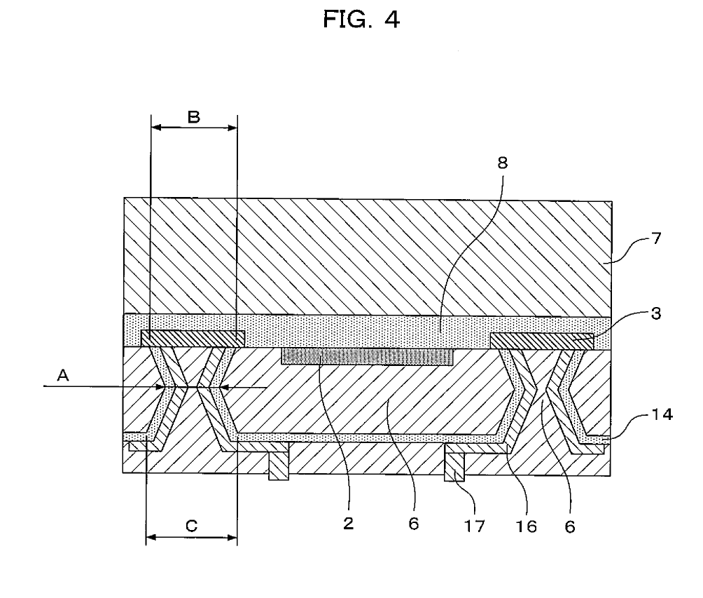

Referring to FIG. 4, a semiconductor image pickup device will be described below as a semiconductor device.

FIG. 4 shows a representative example in which a through-hole conductor portion including an upper through-hole conductor portion 9′ and a lower through-hole conductor portion 9 is not filled with a conductor layer but conductor layers 16 are partially formed unlike in FIG. 2. In the case where pore size A is smaller than pore size B of the upper through-hole conductor portion 9′ and the pore size A is equal to or smaller than pore size C of the lower through-hole conductor portion 9, the same effect can be obtained as the configurations of FIGS. 2 and 3 and it is not necessary to apply the conductor layer over the hole. Thus it is possible to provide a reliable semiconductor image pickup device while suppressing an increase in manufacturing cost.

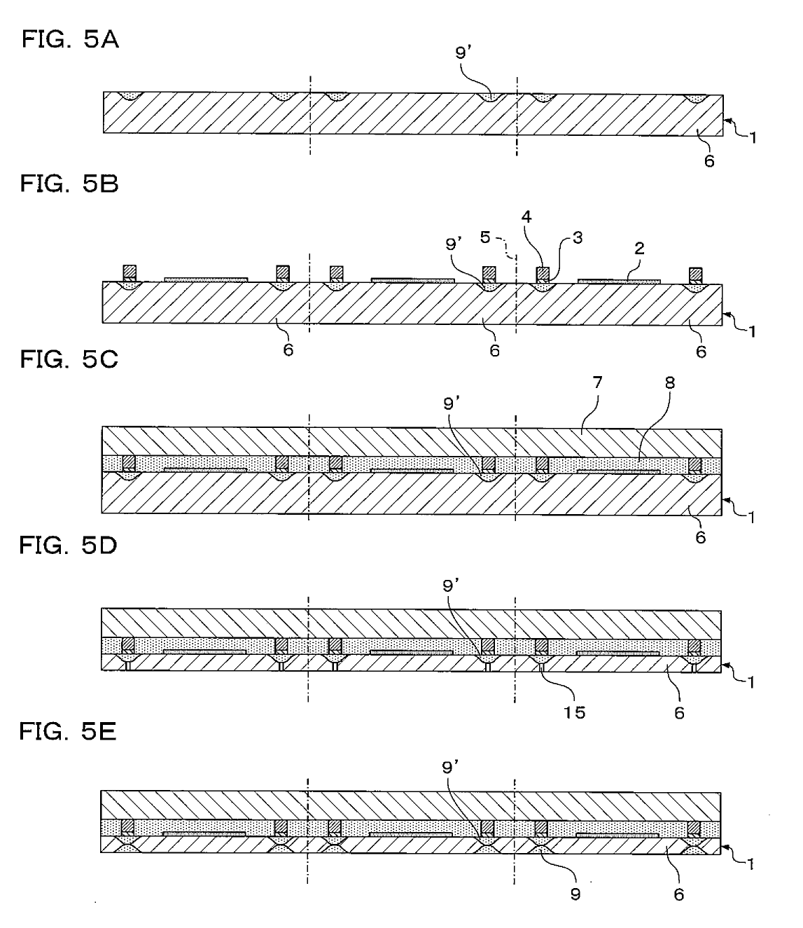

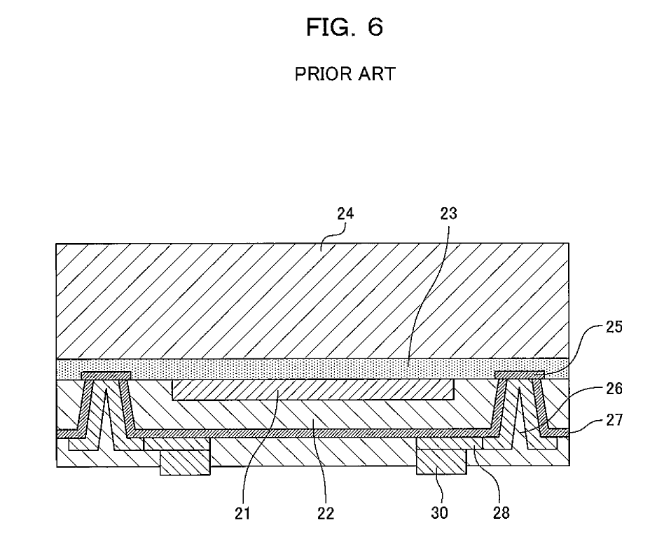

Referring to FIGS. 5A to 5E, a semiconductor image pickup device as a semiconductor device and a method of manufacturing the same will be described below.

In FIGS. 5A to 5E, FIGS. 5A to 5C show the same steps as in FIGS. 1A to 1C. As shown in FIG. 5D, through holes 15 are drilled beforehand to form the lower through-hole conductor portions (conductor layers) 9 of FIG. 2. Thus it is possible to easily form recessed holes for the respective lower through-hole conductor portions 9 in FIG. 5E and suppress an increase in manufacturing cost.

In the completed semiconductor image pickup device, the adhesive 8 has a shrinkage stress at least in the thickness direction. Thus after the semiconductor image pickup device is mounted in equipment, a change in ambient temperature does not cause variations in dimensions between the optical member 7 and the surfaces of the image pickup regions of the semiconductor elements 6. Consequently, the completed semiconductor image pickup device has excellent optical characteristics.

In this explanation, the semiconductor image pickup device that is a kind of light receiving element was described as an example of a semiconductor device. In addition to the semiconductor image pickup device, examples of the light receiving element include a photo IC (not shown).

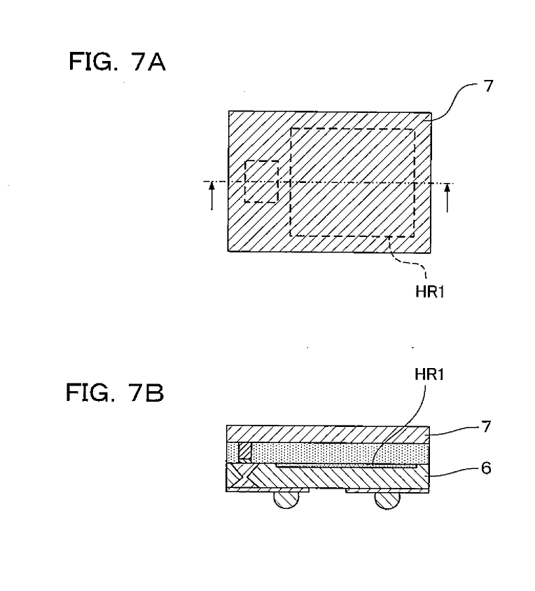

In the present embodiment, examples of the semiconductor device include light receiving devices such as semiconductor image pickup devices and photo ICs. An LED as a kind of light emitting device and a laser light emitting device (not shown) as a kind of light emitting device can be implemented as in the present embodiment and the same effect can be obtained as in the present embodiment. FIG. 7A is a plan view of the LED and FIG. 7B is a sectional view taken along the arrow of FIG. 7A. In the LED, a light emitting region HR1 is formed between the optical member 7 serving as a retaining member and the semiconductor element 6.

In the semiconductor device of the present embodiment, instead of the optical member 7, another semiconductor element on which general functions are selectively configured may be used as a retaining member along with the semiconductor element 6. Thus it is possible to form a general semiconductor device including a silicon interposer of a through-silicon undercut type so as to prevent the lower through-hole conductor portion 9 and the upper through-hole conductor portion 9′ from falling off the semiconductor device.

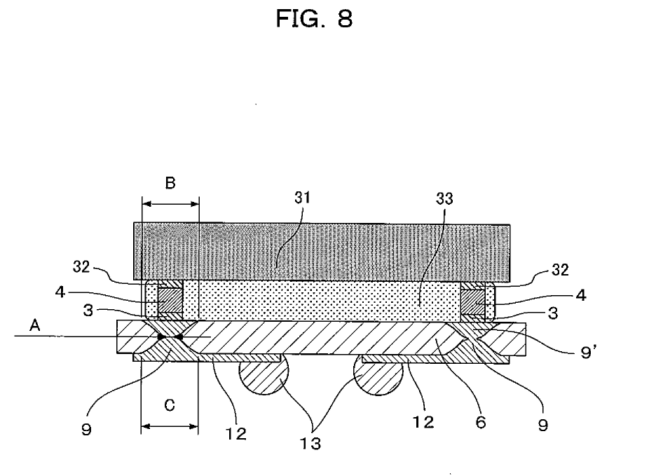

FIG. 8 is a sectional view showing a structural example of a general semiconductor device according to the present embodiment. In the general semiconductor device of FIG. 8, another semiconductor element is used instead of the optical member 7 of the semiconductor device of the present embodiment.

The general semiconductor device includes a semiconductor element 6 and another semiconductor element 31. On the major surface of the semiconductor element 6, electrode portions (first electrode portions) 3 connected to protrusions 4 are formed. The other semiconductor element 31 is a retaining member that covers the protrusions 4 and the electrode portions 3 and is bonded to the semiconductor element 6 while being held by the semiconductor element 6 via the protrusions 4. On the major surface of the other semiconductor element 31, another semiconductor-element electrode portions (second electrode portions) 32 are formed. The other semiconductor element 31 is electrically connected to the semiconductor element 6 in a state in which the other semiconductor-element electrode portions 32 are bonded to the protrusions 4. In the general semiconductor device, through-hole conductor portions (upper and lower through-hole conductor portions 9′ and 9) penetrating the semiconductor element 6 between the major surface and the other surface are formed such that the upper through-hole conductor portion 9′ is increased in pore size from the inside to the major surface of the semiconductor element 6 and the lower through-hole conductor portion 9 is increased in pore size from the inside to the other surface of the semiconductor element 6. The electrode portions 3 are electrically connected to external electrodes 12 formed on the other surface of the semiconductor element 6, via the respective through-hole conductor portions (upper and lower through-hole conductor portions 9′ and 9).

In the general semiconductor device, as shown in FIG. 8, the electrode portions 3 on the semiconductor element 6 and the other semiconductor-element electrode portions 32 on the other semiconductor element 31 are electrically connected via the protrusions 4. In the device of the present embodiment, the protrusions 4 are metallic balls of, e.g., gold or solder.

In order to reduce faulty connections occurring on the electrode portions 3, the protrusions 4, and the other semiconductor-element electrode portions 32 due to an external stress, underfill 33 is injected into a gap between the semiconductor element 6 and the other semiconductor element 31 and increases the bond strength after the electrical connection of the electrode portions 3, the protrusions 4, and the other semiconductor-element electrode portions 32.

In the device of the present embodiment, the underfill 33 is a thermosetting resin. After the underfill 33 is injected into the gap between the semiconductor element 6 and the other semiconductor element 31, the underfill 33 is heated and cured at about 200° C.

Also in this configuration, the upper through-hole conductor portions 9′ are located directly under the electrode portions 3. The joint surface of the upper through-hole conductor portion 9′ and the lower through-hole conductor portion 9 has pore size A that is smaller than pore size B of the upper through-hole conductor portion 9′ on the major surface of the semiconductor element 6 and pore size C of the lower through-hole conductor portion 9 on the other surface of the semiconductor element 6. Thus it is possible to reduce the possibility that the through-hole conductor portion would fall off the semiconductor element due to a stress generated when the semiconductor device is mounted on an electronic device substrate. Thus electrical short circuits between the semiconductor element and the electronic device substrate can be eliminated and a reliable semiconductor device can be provided. Moreover, it is possible to reduce the possibility of small cracks on the through-hole conductor portions 9 and 9′, so that the electrical characteristics of the semiconductor element are not degraded and a reliable semiconductor device can be provided.

In the general semiconductor device, the other semiconductor element 31 may be various function elements including amplifying elements, memory elements, and microcomputer elements, depending on the purpose of use.

FIG. 8 shows a stacked structure including the flip-chip other semiconductor element 31 and the semiconductor element 6. The present invention is not limited to this configuration. The other semiconductor element 31 may have a face-up connection structure in which the other semiconductor element 31 is a through-silicon semiconductor element.

FIG. 8 shows the general semiconductor device that has a stacked structure including the flip-chip other semiconductor element 31 and the semiconductor element 6 and uses the underfill 33 for stabilizing the bonding of the other semiconductor element 31 and the semiconductor element 6. The underfill 33 may be eliminated if a sufficient bond strength is obtained between the other semiconductor element 31 and the semiconductor element 6 against a stress generated when the semiconductor device is mounted on the electronic device substrate.

Having specifically described exemplary embodiments of the present invention, it is easily understood by those skilled in the art that various changes can be made in the exemplary embodiments without substantially departing from a new teaching of the present invention and the effect of the present invention. Therefore, these changes are intended to be embraced in the scope of the present invention.

What is claimed is:

1. A semiconductor device comprising:
a semiconductor element comprising a major surface, an other surface opposite to the major surface, first electrode portions formed on the major surface, protrusions connected on the respective first electrode portions, through-hole conductor portions that are located directly under the respective first electrode portions and penetrate the semiconductor element between the major surface and the other surface, and external electrodes formed on the other surface; and
a retaining member that covers the protrusions and the first electrode portions and is joined to the semiconductor element while being held by the semiconductor element via the protrusions,
wherein the through-hole conductor portions are increased in pore size from inside of the semiconductor element to the major surface and the other surface, and
the first electrode portions are electrically connected to the respective external electrodes via the respective through-hole conductor portions.

2. The semiconductor device according to claim 1, wherein the retaining member is an optical member bonded to the semiconductor element while being in contact with the protrusions.

3. The semiconductor device according to claim 1, wherein the retaining member is another semiconductor element that has second electrode portions and is electrically connected to the semiconductor element with the second electrode portions joined to the respective protrusions.

4. A semiconductor device comprising:
a semiconductor element comprising a major surface, an other surface opposite to the major surface, first electrode portions formed on the major surface, protrusions connected on the respective first electrode portions, through-hole conductor portions that are located directly under the respective first electrode portions and penetrate the semiconductor element between the major surface and the other surface, and external electrodes formed on the other surface; and
a retaining member that covers the protrusions and the first electrode portions and is joined to the semiconductor element while being held by the semiconductor element via the protrusions,
wherein the through-hole conductor portions are increased in pore size from inside of the semiconductor element to the major surface and substantially have a constant pore size from the inside of the semiconductor element to the other surface, and
the first electrode portions are electrically connected to the respective external electrodes via the respective through-hole conductor portions.

5. The semiconductor device according to claim 4, wherein the retaining member is an optical member bonded to the semiconductor element while being in contact with the protrusions.

6. The semiconductor device according to claim 4, wherein the retaining member is another semiconductor element that has second electrode portions and is electrically connected to the semiconductor element with the second electrode portions joined to the respective protrusions.

7. A semiconductor device comprising:
a semiconductor element comprising a major surface, an other surface opposite to the major surface, first electrode portions formed on the major surface, through-hole conductor portions that are located directly under the respective first electrode portions and penetrate the semiconductor element between the major surface and the other surface, and external electrodes formed on the other surface; and
an optical member bonded to the semiconductor element so as to cover the first electrode portions,
wherein the through-hole conductor portions are increased in pore size from inside of the semiconductor element to the major surface, and
the first electrode portions are electrically connected to the respective external electrodes via the respective through-hole conductor portions.

8. The semiconductor device according to claim 7, wherein the through-hole conductor portions are increased in pore size from the inside of the semiconductor element to the major surface and the other surface.

9. The semiconductor device according to claim 7, wherein the through-hole conductor portions are increased in pore size from the inside of the semiconductor element to the major surface and substantially have a constant pore size from the inside of the semiconductor element to the other surface.

10. A method of manufacturing a semiconductor device, comprising the steps of:
forming multiple semiconductor elements in a semiconductor wafer;
forming upper through-hole conductor portions on a major surface of the semiconductor wafer for the semiconductor element such that the upper through-hole conductor portions are increased in pore size from inside of the semiconductor wafer to the major surface;
forming first electrode portions respectively on top surfaces of the upper through-hole conductor portions;
connecting protrusions respectively to top surfaces of the first electrode portions;
joining a retaining member to the semiconductor wafer such that the retaining member covers the protrusions and the first electrode portions and is held by the semiconductor wafer via the protrusions;
forming holes serving as lower through-hole conductor portions nearly under the respective first electrode portions, by polishing an other surface opposite to the major surface of the semiconductor wafer, the holes reaching the upper through-hole conductor portions and being increased in pore size from the inside of the semiconductor wafer to the other surface;
forming an insulating film on inner walls of the holes serving as the lower through-hole conductor portions and the other surface of the semiconductor wafer;
forming the lower through-hole conductor portions and external electrodes by forming a conductor layer on the insulating film on the inner walls of the holes serving as the lower through-hole conductor portions and on the other surface of the semiconductor wafer, the lower through-hole conductor portion being electrically connected to the first electrode portion via the upper through-hole conductor portion, the external electrode being electrically connected to the lower through-hole conductor portion; and
cutting the semiconductor wafer for each of the semiconductor elements to obtain individual semiconductor devices.

11. The method of manufacturing a semiconductor device according to claim 10, wherein the retaining member is an optical member bonded to the semiconductor wafer while being in contact with the protrusions.

12. The method of manufacturing a semiconductor device according to claim 10, wherein the retaining member is another semiconductor element that has second electrode portions and is electrically connected to the semiconductor wafer with the second electrode portions joined to the respective protrusions.

13. A method of manufacturing a semiconductor device, comprising the steps of:
forming multiple semiconductor elements in a semiconductor wafer;
forming upper through-hole conductor portions on a major surface of the semiconductor wafer for the semiconductor element such that the upper through-hole conductor portions are increased in pore size from inside of the semiconductor wafer to the major surface;
forming first electrode portions respectively on top surfaces of the upper through-hole conductor portions;
connecting protrusions respectively to top surfaces of the first electrode portions;
joining a retaining member to the semiconductor wafer such that the retaining member covers the protrusions and the first electrode portions and is held by the semiconductor wafer via the protrusions;
polishing an other surface opposite to the major surface of the semiconductor wafer;
forming holes serving as lower through-hole conductor portions nearly under the respective first electrode portions on the other surface of the semiconductor wafer, the holes reaching the upper through-hole conductor portions and being increased in pore size from the inside of the semiconductor wafer to the other surface or substantially having a constant pore size from the inside of the semiconductor wafer to the other surface;
forming an insulating film on inner walls of the holes serving as the lower through-hole conductor portions and the other surface of the semiconductor wafer;
forming the lower through-hole conductor portions and external electrodes by forming a conductor layer on the insulating film on the inner walls of the holes serving as the lower through-hole conductor portions and on the other surface of the semiconductor wafer, the lower through-hole conductor portion being electrically connected to the first electrode portion via the upper through-hole conductor portion, the external electrode being electrically connected to the lower through-hole conductor portion; and
cutting the semiconductor wafer for each of the semiconductor elements to obtain individual semiconductor devices.

14. The method of manufacturing a semiconductor device according to claim 13, wherein the retaining member is an optical member bonded to the semiconductor wafer while being in contact with the protrusions.

15. The method of manufacturing a semiconductor device according to claim 13, wherein the retaining member is another semiconductor element that has second electrode portions and is electrically connected to the semiconductor wafer with the second electrode portions joined to the respective protrusions.

16. A method of manufacturing a semiconductor device, comprising the steps of:
forming multiple semiconductor elements in a semiconductor wafer;
forming upper through-hole conductor portions on a major surface of the semiconductor wafer for the semiconductor element such that the upper through-hole conductor portions are increased in pore size from inside of the semiconductor wafer to the major surface;
forming first electrode portions respectively on top surfaces of the upper through-hole conductor portions;
bonding an optical member to the semiconductor wafer such that the optical member covers the first electrode portions;
polishing an other surface opposite to the major surface of the semiconductor wafer;
forming holes serving as lower through-hole conductor portions nearly under the respective first electrode portions on the other surface of the semiconductor wafer, the holes reaching the upper through-hole conductor portions and being increased in pore size from the inside of the semiconductor wafer to the other surface or substantially having a constant pore size from the inside of the semiconductor wafer to the other surface;
forming an insulating film on inner walls of the holes serving as the lower through-hole conductor portions and the other surface of the semiconductor wafer;
forming the lower through-hole conductor portions and external electrodes by forming a conductor layer on the insulating film on the inner walls of the holes serving as the lower through-hole conductor portions and on the other surface of the semiconductor wafer, the lower through-hole conductor portion being electrically connected to the first electrode portion via the upper through-hole conductor portion, the external electrode being electrically connected to the lower through-hole conductor portion; and
cutting the semiconductor wafer for each of the semiconductor elements to obtain individual semiconductor devices.
